(19) United States
(12) Patent Application Publication
(10) Pub. No.: US 2024/0253181 A1
(43) Pub. Date: Aug. 1, 2024

(54) METHOD OF CREATING RESPONSIVENESS PROFILE OF POLISHING RATE OF WORKPIECE, POLISHING METHOD, AND COMPUTER-READABLE STORAGE MEDIUM STORING PROGRAM

(71) Applicant: EBARA CORPORATION, Tokyo (JP)

(72) Inventors: Satoru YAMAKI, Tokyo (JP); Keita YAGI, Tokyo (JP); Nachiketa CHAUHAN, Tokyo (JP); Akira NAKAMURA, Tokyo (JP)

(21) Appl. No.: 18/565,046

(22) PCT Filed: May 31, 2022
(86) PCT No.: PCT/JP2022/022102

§ 371 Date: Nov. 28, 2023

(30) Foreign Application Priority Data
Jun. 10, 2021 (JP) 2021-097583

(51) Int. Cl. B24B 49/05; B24B 49/03; B24B 49/16

(52) U.S. Cl. CPC B24B 49/05; B24B 49/03; B24B 49/16

(57) ABSTRACT

The present invention relates to a technique of calculating a responsiveness of a polishing rate to change in a pressure to press a workpiece, such as a wafer, a substrate, or a panel, for use in manufacturing of semiconductor devices, against a polishing pad. A method includes: performing simulation to calculate a pressing-pressure responsiveness profile indicating a distribution of pressing pressure, which is to be applied from the workpiece to a polishing pad (2), changed in response to a change in unit pressure in the pressure chamber of a polishing head (7); pressing the workpiece against the polishing pad to polish the workpiece, while a predetermined pressure is maintained in the pressure chamber; creating a polishing-rate profile indicating a distribution of polishing rate of the polished workpiece; and creating the polishing-rate responsiveness profile based on the pressing-pressure responsiveness profile, the predetermined pressure, and the polishing-rate profile.

### TECHNICAL FIELD

The present invention relates to a technique of polishing a workpiece, such as a wafer, a substrate, or a panel, for use in manufacturing of semiconductor devices, and more particularly, to a technique of calculating a responsiveness of a polishing rate to change in pressure for pressing the workpiece against a polishing pad.

### BACKGROUND ART

Chemical mechanical polishing (hereinafter referred to as CMP) is a process of polishing a workpiece (e.g., a wafer, a substrate, a panel, etc.) by placing the workpiece in sliding contact with a polishing pad while supplying a polishing liquid containing abrasive grains, such as silica (SiO₂), onto the polishing pad. A polishing apparatus for performing the CMP includes a polishing table that supports the polishing pad having a polishing surface, and a polishing head for pressing the workpiece against the polishing pad.

The polishing head is configured to press the workpiece against the polishing pad with an elastic membrane forming a pressure chamber. A compressed gas is supplied into the pressure chamber, and the pressure of the gas is applied to the workpiece through the elastic membrane. Therefore, a force with which the workpiece is pressed against the polishing pad can be regulated by the pressure in the pressure chamber.

The polishing apparatus polishes the workpiece as follows. While the polishing table and the polishing pad are rotated together, a polishing liquid (typically slurry) is supplied onto the polishing surface of the polishing pad. The polishing head presses a surface of the workpiece against the polishing surface of the polishing pad while rotating the workpiece. The workpiece is brought into sliding contact with the polishing pad in the presence of the polishing liquid. The surface of the workpiece is polished by a chemical action of the polishing liquid and mechanical actions of the polishing pad and abrasive grains contained in the polishing liquid.

A film thickness of the workpiece gradually decreases with polishing time. A rate at which the film thickness of the workpiece reduces is often represented by a polishing rate. The polishing rate is an amount of surface material of the workpiece that has been reduced by polishing per unit time, and the amount of reduction is represented by a thickness. The polishing rate is also referred to as a removal rate.

In order to optimize the CMP process, it is important to determine a responsiveness of the polishing rate of the workpiece to a pressure change in the pressure chamber of the polishing head. The responsiveness of the polishing rate means a change in the polishing rate in response to a change in unit pressure in the pressure chamber. Determining the responsiveness of the polishing rate enables the workpiece to be polished at a required polishing rate to achieve a target profile.

### CITATION LIST

### Patent Literature

Patent document 1: Japanese laid-open patent publication No. 2006-43873

### SUMMARY OF INVENTION

### Technical Problem

It is known that the polishing rate basically obeys Preston's law as follows.

polishing rate∝pressing pressure×relative speed

However, the pressing pressure applied to the workpiece from the elastic membrane of the polishing head is not constant within a pressing surface of the elastic membrane, and the pressing pressure varies due to various factors, such as temperature, a polishing pad, and a polishing liquid. Conventionally, the polishing-rate responsiveness is determined by actually polishing workpieces while increasing or decreasing the pressure in the pressure chamber using design of experiments (DOE). However, this approach requires a considerable number of workpieces and a lot of operation time, which entail increased costs.

Thus, the present invention provides a method capable of easily obtaining a responsiveness of polishing rate to a change in pressure for pressing a workpiece, such as a wafer, against a polishing pad. The present invention also provides a polishing method for the workpiece using a polishing-rate responsiveness profile. Furthermore, the present invention provides a computer-readable storage medium storing a program for causing a computer to create the polishing-rate responsiveness profile.

### Solution to Problem

In an embodiment, there is provided a method of creating a polishing-rate responsiveness profile indicating a distribution of responsiveness of a polishing rate to a pressure change in a pressure chamber when a workpiece for use in manufacturing of semiconductor devices is pressed against a polishing pad with an elastic membrane forming the pressure chamber therein, the method comprising: performing simulation to calculate a pressing-pressure responsiveness profile indicating a distribution of pressing pressure, which is to be applied from the workpiece to the polishing pad, changed in response to a change in unit pressure in the pressure chamber; pressing the workpiece against the polishing pad to polish the workpiece, while a predetermined pressure is maintained in the pressure chamber; creating a polishing-rate profile indicating a distribution of polishing rate of the polished workpiece; and creating the polishing-rate responsiveness profile based on the pressing-pressure responsiveness profile, the predetermined pressure, and the polishing-rate profile.

In an embodiment, creating the polishing-rate responsiveness profile comprises: multiplying the pressing-pressure responsiveness profile by the predetermined pressure and a polishing-rate coefficient to create a virtual polishing-rate profile; determining the polishing-rate coefficient that minimizes a difference between the polishing-rate profile and the virtual polishing-rate profile; and multiplying the pressing-pressure responsiveness profile by the determined polishing-rate coefficient to create the polishing-rate responsiveness profile.

In an embodiment, the pressure chamber comprises a plurality of pressure chambers, and the polishing-rate coefficient comprises a plurality of polishing-rate coefficients corresponding to the plurality of pressure chambers, respectively.

In an embodiment, the method further comprises determining a correction factor that eliminates the difference between the polishing-rate profile and the virtual polishing-rate profile, wherein multiplying the pressing-pressure responsiveness profile by the determined polishing-rate coefficient to create the polishing-rate responsiveness profile comprises multiplying the pressing-pressure responsiveness profile by the determined polishing-rate coefficient and the determined correction factor to create the polishing-rate responsiveness profile.

In an embodiment, creating the polishing-rate responsiveness profile comprises: adding a polishing-rate offset to a value determined by multiplying the pressing-pressure responsiveness profile by the predetermined pressure and a polishing-rate coefficient to create a virtual polishing-rate profile; determining the polishing-rate coefficient and the polishing-rate offset that minimize a difference between the polishing-rate profile and the virtual polishing-rate profile; and adding the determined polishing-rate offset to a value determined by multiplying the pressing-pressure responsiveness profile by the determined polishing-rate coefficient to create the polishing-rate responsiveness profile.

In an embodiment, the pressure chamber comprises a plurality of pressure chambers, and the polishing-rate coefficient comprises a plurality of polishing-rate coefficients corresponding to the plurality of pressure chambers, respectively.

In an embodiment, the method further comprises determining a correction factor that eliminates the difference between the polishing-rate profile and the virtual polishing-rate profile, wherein multiplying the pressing-pressure responsiveness profile by the determined polishing-rate coefficient to create the polishing-rate responsiveness profile comprises adding the determined polishing-rate offset to a value determined by multiplying the pressing-pressure responsiveness profile by the determined polishing-rate coefficient and the determined correction factor to create the polishing-rate responsiveness profile.

In an embodiment, creating the pressing-pressure responsiveness profile comprises: performing simulation to create a first pressing-pressure responsiveness profile indicating a distribution of the pressing pressure changed in response to a change from a first pressure to a second pressure in the pressure chamber; performing simulation to create a second pressing-pressure responsiveness profile indicating a distribution of the pressing pressure changed in response to a change from a third pressure to a fourth pressure in the pressure chamber; and creating the pressing-pressure responsiveness profile based on the first pressing-pressure responsiveness profile and the second pressing-pressure responsiveness profile.

In an embodiment, creating the pressing-pressure responsiveness profile based on the first pressing-pressure responsiveness profile and the second pressing-pressure responsiveness profile comprises creating the pressing-pressure responsiveness profile by interpolation or extrapolation using the first pressing-pressure responsiveness profile and the second pressing-pressure responsiveness profile.

In an embodiment, creating the pressing-pressure responsiveness profile based on the first pressing-pressure responsiveness profile and the second pressing-pressure responsiveness profile comprises inputting the first pressing-pressure responsiveness profile and the second pressing-pressure responsiveness profile into a model constructed by machine learning, and outputting the pressing-pressure responsiveness profile from the model.

In an embodiment, the polishing-rate profile comprises one selected from a plurality of polishing-rate profiles created by polishing a plurality of workpieces, and the plurality of polishing-rate profiles are obtained by: pressing the plurality of workpieces one by one against the polishing pad to polish the plurality of workpieces with different pressures set in the pressure chamber for each of the plurality of workpieces; and creating the plurality of polishing-rate profiles indicating distributions of polishing rate of the plurality of polished workpieces.

In an embodiment, the method further comprises optimizing a polishing condition for other workpiece using the polishing-rate responsiveness profile.

In an embodiment, optimizing the polishing condition for the other workpiece comprises: creating a current film-thickness profile of the other workpiece, while the other workpiece is polished; and determining the pressure in the pressure chamber for minimizing a difference between the current film-thickness profile and a target film-thickness profile based on the polishing-rate responsiveness profile.

In an embodiment, optimizing the polishing condition for the other workpiece comprises: creating a film-thickness profile before the polishing of the workpiece and a film-thickness profile after the polishing of the workpiece which has been used to create the polishing-rate profile; and determining the pressure in the pressure chamber based on the film-thickness profile before the polishing, the film-thickness profile after the polishing, a target film-thickness profile, and the polishing-rate responsiveness profile.

In an embodiment, there is provided a polishing method comprising: optimizing a polishing condition for a workpiece using the polishing-rate responsiveness profile created by the method according to any one of claims 1 to 14; and pressing the workpiece against the polishing pad with the elastic membrane to polish the workpiece under the optimized polishing condition.

In an embodiment, there is provided a computer-readable storage medium storing a program to cause a computer to create a polishing-rate responsiveness profile indicating a distribution of responsiveness of a polishing rate to a pressure change in a pressure chamber when a workpiece for use in manufacturing of semiconductor devices is pressed against a polishing pad with an elastic membrane forming the pressure chamber therein, the program being configured to cause the computer to perform the steps of: performing simulation to calculate a pressing-pressure responsiveness profile indicating a distribution of pressing pressure, which is to be applied from the workpiece to the polishing pad, changed in response to a change in unit pressure in the pressure chamber; creating a polishing-rate profile indicating a distribution of polishing rate of the workpiece polished by pressing the workpiece against the polishing pad while a predetermined pressure is maintained in the pressure chamber; and creating the polishing-rate responsiveness profile based on the pressing-pressure responsiveness profile, the predetermined pressure, and the polishing-rate profile.

### Advantageous Effects of Invention

According to the present invention, the polishing-rate responsiveness profile can be easily obtained based on the pressing-pressure responsiveness profile generated by the simulation and the polishing-rate profile obtained by actual polishing.

### BRIEF DESCRIPTION OF DRAWINGS

FIG. 1 is a schematic diagram showing an embodiment of a polishing apparatus;

FIG. 2 is a cross-sectional view showing an embodiment of a polishing head;

FIG. 3 is a flowchart illustrating an embodiment of creating a polishing-rate responsiveness profile;

FIG. 4 is a diagram illustrating an embodiment of creating a pressing-pressure responsiveness profile;

FIG. 5 is a graph showing an example of the pressing-pressure responsiveness profile;

FIG. 6 is a graph showing an example of a virtual polishing-rate profile for each pressure chamber, a virtual polishing-rate profile for all pressure chambers, and an actual polishing-rate profile; and

FIG. 7 is a flowchart illustrating an embodiment of updating a correction factor.

### DESCRIPTION OF EMBODIMENTS

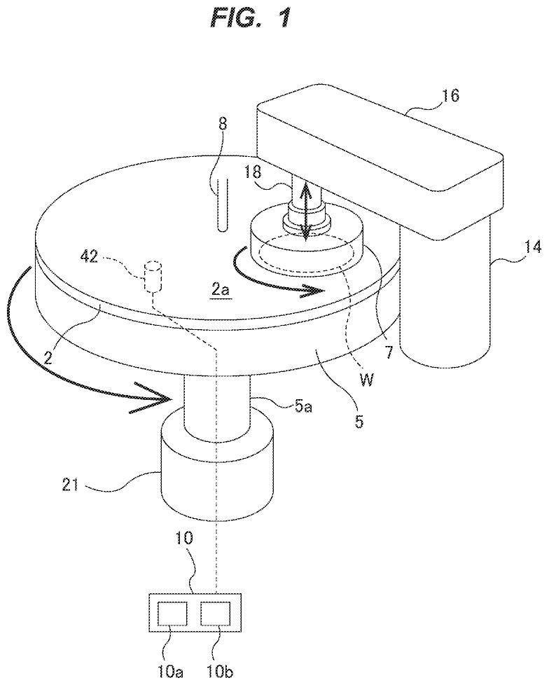

Embodiments of the present invention will now be described with reference to the drawings. FIG. 1 is a schematic diagram showing an embodiment of a polishing apparatus. The polishing apparatus is configured to chemically and mechanically polish a wafer W, which is an example of a workpiece for use in manufacturing of semiconductor devices. As shown in FIG. 1, this polishing apparatus includes a polishing table 5 configured to support a polishing pad 2 having a polishing surface 2a, a polishing head 7 configured to press the wafer W against the polishing surface 2a, a polishing-liquid supply nozzle 8 configured to supply a polishing liquid (e.g., slurry containing abrasive grains) onto the polishing surface 2a, and an arithmetic system 10 configured to create a polishing-rate responsiveness profile, which will be described later.

The polishing head 7 is configured to be able to hold the wafer W on its lower surface. The wafer W has a film to be polished. In the following embodiments, a wafer is used as an example of the workpiece, but the workpiece is not limited to the wafer, and may be a circular substrate, a rectangular substrate, a panel, etc., as long as they are for use in manufacturing of semiconductor devices.

The arithmetic system 10 is composed of at least one computer. The arithmetic system 10 includes a memory 10a storing programs for creating the polishing-rate responsiveness profile, which will be described later, and an arithmetic device 10b configured to perform arithmetic operations according to instructions contained in the programs. The memory 10a includes a main memory, such as a random-access memory (RAM), and an auxiliary memory, such as a hard disk drive (HDD) or a solid state drive (SSD). Examples of the arithmetic device 10b include a CPU (central processing unit) and a GPU (graphic processing unit). However, the specific configuration of the arithmetic system 10 is not limited to these examples.

The polishing apparatus further includes a support shaft 14, a polishing-head oscillation arm 16 coupled to an upper end of the support shaft 14, and a polishing-head shaft 18 rotatably supported by a free end of the polishing-head oscillation arm 16. The polishing head 7 is fixed to a lower end of the polishing-head shaft 18. A polishing-head rotating mechanism (not shown) having an electric motor and other elements is disposed in the polishing-head oscillation arm 16. This polishing-head rotating mechanism is coupled to the polishing-head shaft 18, and is configured to rotate the polishing-head shaft 18 and the polishing head 7 in a direction indicated by an arrow.

The polishing-head shaft 18 is coupled to a not-shown polishing-head elevating mechanism (including a ball screw mechanism or the like). The polishing-head elevating mechanism is configured to vertically move the polishing-head shaft 18 relative to the polishing-head oscillation arm 16. The vertical movement of the polishing-head shaft 18 allows the polishing head 7 to move vertically relative to the polishing-head oscillation arm 16 and the polishing table 5 as indicated by an arrow.

The polishing apparatus further includes a table rotating motor 21 configured to rotate the polishing pad 2 and the polishing table 5 about their own axes. The table rotating motor 21 is disposed below the polishing table 5, and the polishing table 5 is coupled to the table rotating motor 21 via a table shaft 5a. The polishing table 5 and the polishing pad 2 are rotated by the table rotating motor 21 about the table shaft 5a in a direction indicated by an arrow. The polishing pad 2 is attached to an upper surface of the polishing table 5. An exposed surface of the polishing pad 2 constitutes the polishing surface 2a for polishing the wafer W.

Polishing of the wafer W is performed as follows. The wafer W, with its surface to be polished facing downward, is held by the polishing head 7. While the polishing head 7 and the polishing table 5 are rotating independently, the polishing liquid (e.g., slurry containing abrasive grains) is supplied onto the polishing surface 2a of the polishing pad 2 from the polishing-liquid supply nozzle 8 provided above the polishing table 5. The polishing pad 2 rotates about its central axis together with the polishing table 5. The polishing head 7 is moved to a predetermined height by the polishing-head elevating mechanism (not shown). Further, while the polishing head 7 is maintained at the above predetermined height, the polishing head 7 presses the wafer W against the polishing surface 2a of the polishing pad 2. The wafer W rotates together with the polishing head 7. The wafer W is brought into sliding contact with the polishing surface 2a in the presence of the polishing liquid on the polishing surface 2a of the polishing pad 2. The surface of the wafer W is polished by a combination of a chemical action of the polishing liquid and mechanical actions of the polishing pad 2 and the abrasive grains contained in the polishing liquid.

The polishing apparatus includes a film-thickness sensor 42 configured to measure a film thickness of the wafer W on the polishing surface 2a. The film-thickness sensor 42 is configured to generate a polishing index value that directly or indirectly indicates the film thickness of the wafer W. Since this polishing index value varies according to the film thickness of the wafer W, the polishing index value indicates the film thickness of the wafer W. The polishing index value may be a value representing the film thickness of the wafer W itself, or may be a physical quantity or a signal value before being converted into the film thickness.

Examples of the film-thickness sensor 42 include an optical film-thickness sensor and an eddy-current sensor. The optical film-thickness sensor is configured to irradiate the surface of the wafer W with light, and determine the film thickness of the wafer W from spectrum of reflected light from the wafer W. The eddy-current sensor is configured to induce an eddy current in a conductive film formed on the wafer W, and output a signal value that varies according to an impedance of an electrical circuit including the conductive film and a coil of the eddy-current sensor. The optical film-thickness sensor and the eddy-current sensor to be used may be known devices.

The film-thickness sensor 42 is disposed in the polishing table 5, and rotates together with the polishing table 5. More specifically, the film-thickness sensor 42 is configured to measure the film thickness at a plurality of measurement points on the wafer W while moving across the wafer W on the polishing surface 2a each time the polishing table 5 makes one rotation. In this embodiment, the film-thickness sensor 42 is arranged so as to measure the film thickness at a plurality of measurement points including the center of the wafer W. Therefore, the plurality of measurement points are aligned in a radial direction of the wafer W.

The film-thickness sensor 42 is coupled to the arithmetic system 10. The measurement values of the film thickness produced by the film-thickness sensor 42 are monitored by the arithmetic system 10. More specifically, the measurement values of the film thickness at the plurality of measurement points of the wafer W are output from the film-thickness sensor 42, are transmitted to the arithmetic system 10, and are stored in the memory 10a. The arithmetic system 10 creates a film-thickness profile of the wafer W based on the measurement values of the film thickness. The film-thickness profile represents a distribution of film thicknesses along the radial direction of the wafer W.

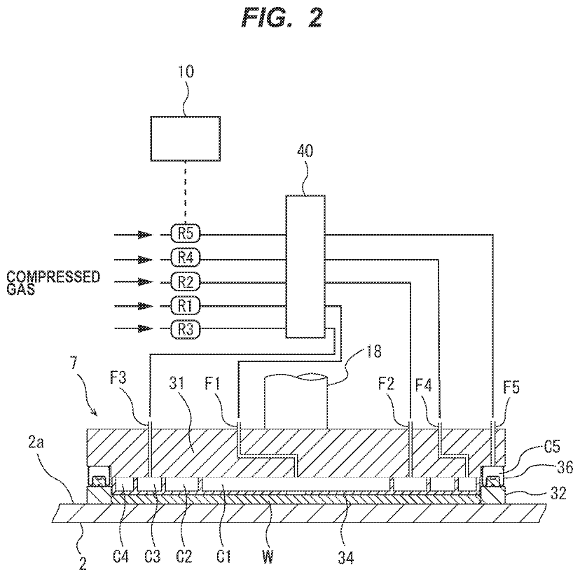

Next, the polishing head 7 will be described. FIG. 2 is a cross-sectional view showing an embodiment of the polishing head 7. The polishing head 7 includes a head body 31 fixed to the end of the polishing-head shaft 18, an elastic membrane 34 attached to a lower portion of the head body 31, and a retainer ring 32 arranged below the head body 31. The retainer ring 32 is arranged around the elastic membrane 34. The retainer ring 32 is an annular structure configured to retain the wafer W so as to prevent the wafer W from being ejected from the polishing head 7 during polishing of the wafer W.

Four pressure chambers C1, C2, C3, and C4 are provided between the elastic membrane 34 and the head body 31. The pressure chambers C1, C2, C3 and C4 are formed by the elastic membrane 34 and the head body 31. The central pressure chamber C1 has a circular shape, and the other pressure chambers C2, C3, and C4 have an annular shape. These pressure chambers C1, C2, C3, and C4 are in a concentric arrangement.

Gas delivery lines F1, F2, F3, and F4 are coupled to the pressure chambers C1, C2, C3, and C4, respectively. Ends of the gas delivery lines F1, F2, F3, and F4 are coupled to a compressed-gas supply source (not shown), which is provided as one of utilities in a factory in which the polishing apparatus is installed. A compressed gas, such as a compressed air, is supplied into the pressure chambers C1, C2, C3, and C4 through the gas delivery lines F1, F2, F3, and F4, respectively. The compressed gas in the pressure chambers C1, C2, C3, and C4 presses the wafer W against the polishing surface 2a of the polishing pad 2 through the elastic membrane 34.

The gas delivery line F3, which communicates with the pressure chamber C3, is coupled to a vacuum line (not shown), so that a vacuum can be formed in the pressure chamber C3. The elastic membrane 34 has an opening in a portion that forms the pressure chamber C3, so that the wafer W can be held by the polishing head 7 via vacuum suction by producing a vacuum in the pressure chamber C3. Further, the wafer W can be released from the polishing head 7 by supplying the compressed gas into the pressure chamber C3.

An annular elastic membrane 36 is provided between the head body 31 and the retainer ring 32. A pressure chamber C5 is formed in the elastic membrane 36. The pressure chamber C5 communicates with the above-described compressed-gas supply source through a gas delivery line F5. The compressed gas is supplied into the pressure chamber C5 through the gas delivery line F5, so that the compressed gas in the pressure chamber C5 presses the retainer ring 32 against the polishing pad 2.

The gas delivery lines F1, F2, F3, F4, and F5 extend via a rotary joint 40 attached to the polishing-head shaft 18. The gas delivery lines F1, F2, F3, F4, and F5, communicating with the pressure chambers C1, C2, C3, C4, and C5, respectively, are provided with pressure regulators R1, R2, R3, R4, and R5, respectively. The compressed gas from the compressed-gas supply source is supplied through the pressure regulators R1 to R5 into the pressure chambers C1 to C5, respectively and independently. The pressure regulators R1 to R5 are configured to regulate the pressures of the compressed gases in the pressure chambers C1 to C5.

The pressure regulators R1 to R5 can independently change the pressures in the pressure chambers C1 to C5 to thereby independently adjust pressing pressures on corresponding four areas of the wafer W, i.e., a central portion, an inner intermediate portion, an outer intermediate portion, and an edge portion, and a pressing pressure of the retainer ring 32 against the polishing pad 2. The gas delivery lines F1, F2, F3, F4, and F5 are coupled to vent valves (not shown), respectively, so that the pressure chambers C1 to C5 can be vented to the atmosphere. In this embodiment, the elastic membrane 34 forms the four pressure chambers C1 to C4, while in one embodiment, the elastic membrane 34 may form less than four pressure chambers or more than four pressure chambers. Only a single pressure chamber may be provided.

The pressure regulators R1 to R5 are coupled to the arithmetic system 10. The arithmetic system 10 receives the measurement value of the film thickness of the wafer W from the film-thickness sensor 42 (see FIG. 1), determines target pressure values of the pressure chambers C1 to C5 based on the measurement value of the film thickness for achieving a target film-thickness profile, and transmits the target pressure values to the pressure regulators R1 to R5, respectively. The pressure regulators R1 to R5 operate so as to maintain the pressures in the pressure chambers C1 to C5 at the corresponding target pressure values.

The polishing head 7 can apply independent pressures to the plurality of areas of the wafer W, respectively. For example, the polishing head 7 can press the different areas of the surface of the wafer W at different pressures against the polishing surface 2a of the polishing pad 2. Therefore, the polishing head 7 can control the film-thickness profile of the wafer W so as to achieve the target film-thickness profile.

In order to optimize the polishing process, it is important to determine a responsiveness of a polishing rate of the wafer W to the pressures in the pressure chambers C1 to C4. The polishing rate is an amount of surface material of the wafer W that been reduced by polishing per unit time, and the amount of reduction is represented by a thickness. The polishing rate is also referred to as a removal rate. The responsiveness of the polishing rate represents a change in the polishing rate in response to a change in unit pressure in the pressure chamber.

In the embodiments described below, the arithmetic system 10 creates a polishing-rate responsiveness profile indicating a distribution of the responsiveness of the polishing rate to pressure changes in the pressure chambers C1 to C4 when the elastic membrane 34 of the polishing head 7 presses the wafer W against the polishing pad 2.

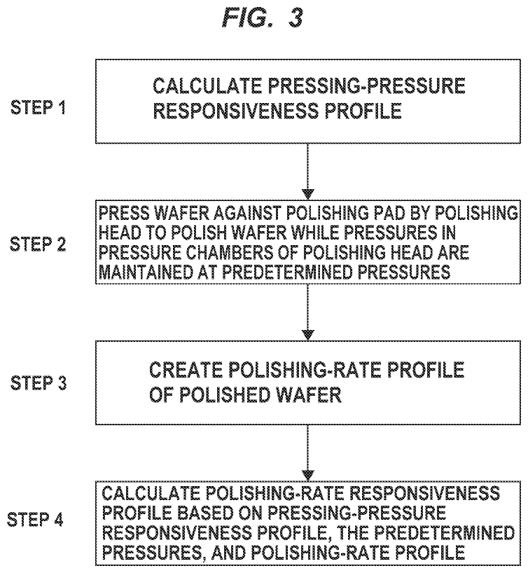

FIG. 3 is a flowchart illustrating an embodiment of creating the polishing-rate responsiveness profile.

In step 1, the arithmetic system 10 performs simulation to calculate a pressing-pressure responsiveness profile indicating distributions of the pressing pressures, which are to be applied from the wafer W to the polishing pad 2, changed in response to changes in unit pressure in the pressure chambers C1 to C4. The simulation is performed using mathematical models of the elastic membrane 34 of the polishing head 7, the polishing pad 2, and the wafer. Thus, a shape and an elasticity of the elastic membrane 34, an elasticity of the polishing pad 2, and a rigidity of the wafer W are reflected in the simulation result. The simulation is not limited as long as it can calculate an intended pressing-pressure responsiveness profile, while in this embodiment, a simulation is based on the finite element method. The simulation in this embodiment is performed under a condition that the wafer W and the polishing pad 2 are not rotated, while the simulation may be performed under a condition that the wafer W and the polishing pad 2 are rotated as in the actual polishing.

In step 2, the polishing apparatus shown in FIG. 1 presses the wafer W against the polishing pad 2 by the polishing head 7 to polish the wafer W while the pressures in the pressure chambers C1 to C4 of the polishing head 7 are maintained at predetermined pressures. The polishing of the wafer W is performed, as described above, by pressing the surface (surface to be polished) of the wafer W against the polishing surface 2a by the polishing head 7 in the presence of the polishing liquid on the polishing surface of the polishing pad 2, while the polishing table 5 and the polishing pad 2 are rotated and the wafer W is rotated by the polishing head 7.

During polishing of the wafer W, the film-thickness sensor 42 measures the film thickness at the plurality of measurement points on the wafer W while the film-thickness sensor 42 moves across the wafer W. In this embodiment, the plurality of measurement points are aligned along the radial direction of the wafer W. The measurement values of the film thickness are transmitted from the film-thickness sensor 42 to the arithmetic system 10. The polishing of the wafer W terminates when the film thickness of the wafer W reaches a target value. The film-thickness sensor 42 continuously measures the film thickness of the wafer W from the start to the end of polishing of the wafer W, and transmits the measurement values of the film thickness to the arithmetic system 10.

In step 3, the arithmetic system 10 creates a polishing-rate profile indicating a distribution of the polishing rate of the polished wafer W. This polishing-rate profile represents a polishing rate at each radial position on the wafer W.

In step 4, the arithmetic system 10 creates a polishing-rate responsiveness profile based on the pressing-pressure responsiveness profile calculated in the step 1, the predetermined pressures in the pressure chambers C1 to C4 set in the step 2, and the polishing-rate profile calculated in the step 3. The polishing-rate responsiveness profile is a distribution of responsiveness of the polishing rate to pressure changes in the pressure chambers C1 to C4 at a plurality of radial positions (i.e., at the plurality of film-thickness measurement points) on the wafer W. The arithmetic system 10 can correctly determine the pressures in the pressure chambers C1 to C4 for achieving the target film-thickness profile based on the polishing-rate responsiveness profile.

Each of the steps will be described in detail below.

FIG. 4 is a diagram illustrating an embodiment of calculating the pressing-pressure responsiveness profile in the step 1 shown in FIG. 3. Vertical axis in FIG. 4 represents pressure applied from the wafer W to the polishing surface 2a of the polishing pad 2 (hereinafter, referred to as pressing pressure), and horizontal axis represents radial position on the wafer W. The horizontal axis in FIG. 4 showing a case where the radius of the wafer W is 150 mm, but the radius of the wafer W is not limited to the example of FIG. 4.

First, a distribution (indicated by a reference symbol CP1+) of the pressing pressure when a gas having a first pressure is supplied into the pressure chamber C1 shown in FIG. 2 is calculated by the simulation. Next, a distribution (indicated by a reference symbol CP1−) of the pressing pressure when a gas having a second pressure is supplied into the same pressure chamber C1 is calculated by the simulation. Both the first pressure and the second pressure are preset pressures, and the first pressure is higher than the second pressure.

Similarly, a distribution (indicated by a reference symbol CP2+) of the pressing pressure when a gas having the first pressure is supplied into the pressure chamber C2, a distribution (indicated by a reference symbol CP2−) of the pressing pressure when a gas having the second pressure is supplied into the pressure chamber C2, a distribution (indicated by a reference symbol CP3+) of the pressing pressure when a gas having the first pressure is supplied into the pressure chamber C3, a distribution (indicated by a reference symbol CP3−) of the pressing pressure when a gas having the second pressure is supplied into the pressure chamber C3, a distribution (indicated by a reference symbol CP4+) of the pressing pressure when a gas having the first pressure is supplied to the pressure chamber C4, and a distribution (indicated by a reference symbol CP4−) of the pressing pressure when a gas having the second pressure is supplied into the pressure chamber C4 are calculated by the simulation.

Next, the arithmetic system 10 calculates a pressing pressure changed in response to a change in unit pressure of the gas in the pressure chamber C1 by dividing a difference between the pressing pressure CP1+ and the pressing pressure CP1− by a difference between the first pressure and the second pressure at each radial position on the wafer W. Similarly, the arithmetic system 10 calculates a pressing pressure changed in response to a change in unit pressure of the gas in the pressure chamber C2 by dividing a difference between the pressing pressure CP2+ and the pressing pressure CP2− by the difference between the first pressure and the second pressure at each radial position on the wafer W, calculates a pressing pressure changed in response to a change in unit pressure of the gas in the pressure chamber C3 by dividing a difference between the pressing pressure CP3+ and the pressing pressure CP3− by the difference between the first pressure and the second pressure at each radial position on the wafer W, and calculates a pressing pressure changed in response to a change in unit pressure of the gas in the pressure chamber C4 by dividing a difference between the pressing pressure CP4+ and the pressing pressure CP4− by the difference between the first pressure and the second pressure at each radial position on the wafer W.

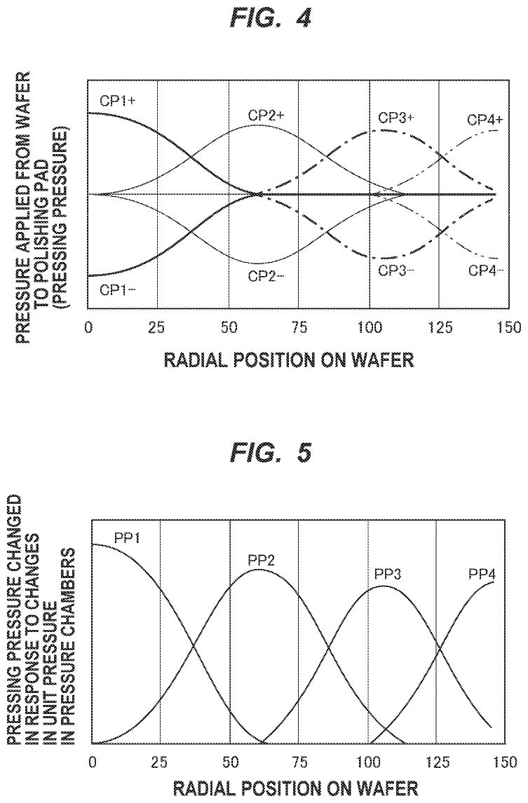

FIG. 5 is a graph showing an example of the pressing-pressure responsiveness profile. Vertical axis in FIG. 5 represents pressing pressure changed in response to the change in the unit pressure in the pressure chamber, and horizontal axis represents radial position on the wafer W. A reference symbol PP1 in FIG. 5 represents a distribution of the pressing pressure changed in response to the change in the unit pressure of the gas in the pressure chamber C1, a reference symbol PP2 represents a distribution of the pressing pressure changed in response to the change in the unit pressure of the gas in the pressure chamber C2, a reference PP3 represents a distribution of the pressing pressure changed in response to the change in the unit pressure of the gas in the pressure chamber C3, and a reference symbol PP4 represents a distribution of the pressing pressure in response to the change in the unit pressure of the gas in the pressure chamber C4. In this manner, the arithmetic system 10 creates the pressing-pressure responsiveness profile.

As described with reference to FIG. 4, the pressing-pressure responsiveness profile is created by performing the simulation under the condition that the pressures in the pressure chambers C1 to C4 are set to the first pressure and the second pressure which are preset values. The pressing-pressure responsiveness profile may change depending on the set values of the pressures in the pressure chambers C1 to C4. The pressures in the pressure chambers C1 to C4 in the actual polishing of the wafer may also change depending on the wafer structure, the film thickness, etc.

Thus, in one embodiment, the arithmetic system 10 performs the simulation multiple times while setting the pressures in the pressure chambers C1 to C4 to a plurality of different values to further calculate (create) the pressing-pressure responsiveness profile. For example, the arithmetic system 10 creates a plurality of pressing-pressure responsiveness profiles by performing the simulation to calculate a first pressing-pressure responsiveness profile indicating distributions of the pressing pressure changed in response to a change from first pressure to second pressure in the pressure chambers C1 to C4, and a second pressing-pressure responsiveness profile indicating distributions of the pressing pressure changed in response to a change from third pressure to fourth pressure in the pressure chambers C1 to C4. The third pressure and the fourth pressure are different from the first pressure and the second pressure.

The arithmetic system 10 may further create a new pressing-pressure responsiveness profile by interpolation or extrapolation using the plurality of pressing-pressure responsiveness profiles calculated by the simulation. In one embodiment, the arithmetic system 10 may further create the pressing-pressure responsiveness profile by inputting the plurality of pressing-pressure responsiveness profiles created by the simulation into a model constructed by machine learning, and outputting a new pressing-pressure responsiveness profile from the model. The plurality of pressing-pressure responsiveness profiles created in this manner are stored in the memory 10a of the arithmetic system 10. The arithmetic system 10 creates the polishing-rate responsiveness profile in the step 4 by using one of the plurality of pressing-pressure responsiveness profiles.

The above-described embodiments relate to the pressure for pressing the wafer W against the polishing pad 2 by the elastic membrane 34 of the polishing head 7. In one embodiment, the pressing-pressure responsiveness profile may include the pressure for pressing the retainer ring 32 of the polishing head 7 against the polishing pad 2. More specifically, the simulation may be performed using mathematical models of the elastic membrane 34 of the polishing head 7, the polishing pad 2, the retainer ring 32, and the wafer W.

Next, the step 2 will be described in detail. In this step 2, the wafer W is actually polished. The polishing apparatus shown in FIG. 1 presses the wafer W against the polishing pad 2 by the polishing head 7 to polish the wafer W while the pressures in the pressure chambers C1 to C4 of the polishing head 7 are maintained at predetermined pressures. The pressures in the pressure chambers C1, C2, C3, and C4 of the polishing head 7 are set to predetermined pressures SP1, SP2, SP3, and SP4, respectively. In one example, the predetermined pressures SP1, SP2, SP3, and SP4 are lower than or equal to the first pressure used in the above-described step 1 and are higher than or equal to the second pressure. The predetermined pressures SP1, SP2, SP3, and SP4 may be different from each other, or some or all of them may be the same. The polishing of the wafer W is performed at least until the film thickness of the wafer W reaches a target value. The film-thickness sensor 42 continuously measures the film thickness of the wafer W from the start to the end of polishing of the wafer W, and transmits the measurement values of the film thickness to the arithmetic system 10.

Next, the step 3 will be described in detail. In this step 3, the arithmetic system 10 calculates polishing rates at the plurality of measurement points on the wafer W by dividing a difference between an initial film thickness and a final film thickness at each of the plurality of measurement points by a polishing time for the wafer W. The initial film thickness is a film thickness before the polishing of the wafer W, and the final film thickness is a film thickness at the end of the polishing of the wafer W. The arithmetic system 10 creates a polishing-rate profile by allotting the calculated polishing rates to the plurality of measurement points.

In the actual polishing of the wafer, set pressures in the pressure chambers C1 to C4 may change depending on the wafer structure, the film thickness, or the like. Thus, in one embodiment, a plurality of polishing-rate profiles may be created by polishing a plurality of wafers with different pressures set in the pressure chambers C1 to C4. More specifically, the plurality of wafers are pressed one by one against the polishing pad 2 with different pressures set in the pressure chambers C1 to C4 for each of the plurality of wafers, so that these plurality of wafers are polished. The arithmetic system 10 produces the plurality of polishing-rate profiles indicating distributions of the polishing rate of the plurality of polished wafers. The plurality of polishing-rate profiles created in this manner are stored in the memory 10a of the arithmetic system 10. The arithmetic system 10 creates the polishing-rate responsiveness profile in the step 4 by using one of the plurality of polishing-rate profiles.

Next, the step 4 will be described in detail. In this step 4, the arithmetic system 10 calculates by using the following formulae stored in the memory 10a,

$${\sum }_{r = 0}^{ra} \vert Rate ( r ) - {\sum }_{n = 1}^{n t} [ AP ( n ) * F ( n ) * P ( n , r ) ] \vert \qquad ( 1 )$$

$$Resp ( n , r ) = F ( n ) * P ( n , r ) \qquad ( 2 )$$

where r is a radial position on the wafer W, ra is the radius of the wafer W, Rate (r) is a polishing rate (actually-measured value) at the radial position r, n is the number of the pressure chamber, nt is a total number of pressure chambers (nt=4 in the embodiment shown in FIG. 2), AP(n) is a pressure of the gas in a n-th pressure chamber when the wafer W is actually polished, F(n) is a polishing-rate coefficient for the n-th pressure chamber, P(n, r) is a responsiveness of the pressing pressure at the radial position r for the n-th pressure chamber, and Resp(n, r) is a polishing-rate responsiveness at the radial position r for the n-th pressure chamber.

The arithmetic system 10 calculates a virtual polishing-rate profile by multiplying the pressing-pressure responsiveness profile by a candidate for the polishing-rate coefficient F(n) and a predetermined pressure AP(n) and determines the polishing-rate coefficient F(n) that minimizes a difference (absolute value) between the actual polishing-rate profile and the virtual polishing-rate profile which is represented by the formula (1). A known algorithm, such as an optimization method, can be applied to determine the polishing-rate coefficient F(n) that minimizes the above formula (1).

The polishing-rate coefficient F(n) is a polishing-rate coefficient for the n-th pressure chamber, while the same polishing-rate coefficient F(n) may be used for all the pressure chambers C1 to C4. Alternatively, a plurality of polishing-rate coefficients F(n) corresponding to the plurality of pressure chambers C1 to C4, respectively, may be used. Compared with the former, the latter can more minimize the difference between the actual polishing-rate profile and the virtual polishing-rate profile represented by the above formula (1).

The arithmetic system 10 further multiplies the pressing-pressure responsiveness profile by the determined polishing-rate coefficient F(n) to thereby calculate (create) the polishing-rate responsiveness profile represented by the formula (2).

A second method of the step 4 will be described.

It is known that the polishing rate may be proportional to the pressing pressure, as indicated by Preston's law, while in one embodiment, the polishing rate can be represented including a polishing-rate offset which is independent of the pressure, as follows:

$$polishing rate = pressing pressure \times polishing ‐ rate + polishing ‐ rate offset$$

Both the optimum polishing-rate responsiveness and polishing-rate offset can be derived by using polishing data of multiple (two or more) wafers polished in advance. It is preferable to obtain the polishing data of the multiple wafers with different pressing pressures.

In this second method of the step 4, the arithmetic system 10 uses the following formulae stored in the memory 10a,

$${\sum }_{m = 1}^{mw} ( {\sum }_{r = 0}^{ra} \vert Rate ( m , r ) - ( {\sum }_{n = 1}^{n t} [ AP ( m , n ) * F ( n ) * P ( n , r ) ] + Offset ( r ) ) \vert ) \qquad ( {1}^{′} )$$

$$Resp ( n , r ) = F ( n ) * P ( n , r ) + Offset ( r ) \qquad ( {2}^{′} )$$

where mw is the number of wafers used in the calculation, r is a radial position on the wafer, ra is the radius of the wafer, Rate (m, r) is a polishing rate (actually-measured value) at a radial position r on a m-th wafer, n is the number of the pressure chamber, nt is a total number of pressure chambers (nt=4 in the embodiment shown in FIG. 2), AP(m, n) is a pressure of the gas in the n-th pressure chamber when the m-th wafer is actually polished, F(n) is a polishing-rate coefficient for the n-th pressure chamber, P(n, r) is a responsiveness of the pressing pressure at the radial position r for the n-th pressure chamber, Resp(n, r) is a polishing-rate responsiveness at the radial position r for the n-th pressure chamber, and Offset(r) is the polishing-rate offset at the radial position r on the wafer.

In this second method, the number of wafers required to obtain the polishing-rate profile in the step 2 can also be less than the total number of pressure chambers C1 to C4 of the polishing head 7.

The arithmetic system 10 multiplies the pressing-pressure responsiveness profile by a candidate for the polishing-rate coefficient F(n) and a predetermined pressure AP(n) and further adds a candidate for the polishing-rate offset Offset(r) to thereby calculate a virtual polishing-rate profile and then determines the polishing-rate coefficient F(n) and the polishing-rate offset Offset(r) that minimize a difference (absolute value) between the actual polishing-rate profile and the virtual polishing-rate profile which is represented by the above formula (1′). A known algorithm, such as an optimization method, can be applied to determine the polishing-rate coefficient F(n) and the polishing-rate offset Offset(r) that minimize the above formula (1′).

The polishing-rate coefficient F(n) is a polishing-rate coefficient for the n-th pressure chamber. In one embodiment, the same polishing-rate coefficient F(n) may be used for all the pressure chambers C1 to C4. Alternatively, a plurality of polishing-rate coefficients F(n) corresponding to the plurality of pressure chambers C1 to C4, respectively, may be used. Compared to the former, the latter can more minimize the difference between the actual polishing-rate profile and the virtual polishing-rate profile represented by the above formula (1′).

The arithmetic system 10 further adds the determined polishing-rate offset Offset(r) to a value which is determined by multiplying the pressing-pressure responsiveness profile by the determined polishing-rate coefficient F(n) to thereby calculate (create) the polishing-rate responsiveness profile represented by the formula (2′).

The following formula (1″) may be used instead of the formula (1′).

$${\sum }_{m = 1}^{mw} ( {\sum }_{r = 0}^{ra} {\vert Rate ( r ) - ( {\sum }_{n = 1}^{n t} [ AP ( n ) * F ( n ) * P ( n , r ) ] + Offset ( r ) ) \vert}^{2} ) \qquad ( {1}^{′′} )$$

Using the above formula (1′) allows a well-known optimization algorithm, such as the least squares method or the quadratic programming method, to be used for determining F(n) and Offset(r). In the case of using this formula (1′), the number of wafers required to obtain the polishing-rate profile in the step 2 can also be less than the total number of pressure chambers C1 to C4 of the polishing head 7.

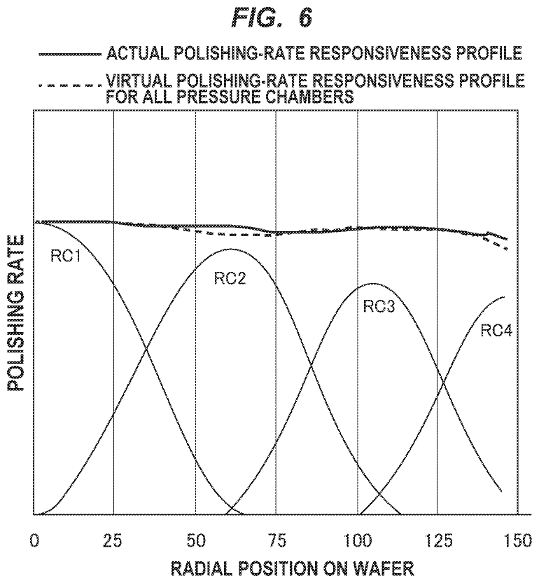

FIG. 6 is a graph showing an example of the virtual polishing-rate profile for each pressure chamber, the virtual polishing-rate profile for all the pressure chambers C to C4, and the actual polishing-rate profile. Vertical axis in FIG. 6 represents polishing rate, and horizontal axis represents radial position on the wafer. A reference symbol RC1 in FIG. 6 represents the virtual polishing-rate profile for the pressure chamber C1, a reference symbol RC2 represents the virtual polishing-rate profile for the pressure chamber C2, a reference symbol RC3 represents the virtual polishing-rate profile for the pressure chamber C3, and a reference symbol RC4 represents the virtual polishing-rate profile for the pressure chamber C4. The virtual polishing-rate profile for all the pressure chambers C1 to C4 is the sum of the virtual polishing-rate profiles RC1, RC2, RC3, and RC4.

As shown in FIG. 6, the difference between the virtual polishing-rate profile and the actual polishing-rate profile is very small. Therefore, the arithmetic system 10 can create a profile of the responsiveness of the polishing-rate per unit pressure in the pressure chambers C1 to C4 using the above formulae (2) or (2′). In particular, according to the embodiment, the polishing-rate responsiveness profile can be easily obtained based on the pressing-pressure responsiveness profile generated by the simulation and the polishing-rate profile obtained by the actual polishing. Furthermore, the number of wafers (workpieces) and working time for obtaining the polishing-rate responsiveness can be reduced. Specifically, the number of wafers actually polished in the step 2 can be reduced. The number of wafers actually polished in the step 2 may be one or more, and the number of wafers required to obtain the polishing-rate profile in the step 2 can be less than the total number of pressure chambers C1 to C4 of the polishing head 7.

Furthermore, the polishing-rate responsiveness profile obtained as described above can be used to optimize polishing conditions for other wafer to be polished next. In one embodiment, the arithmetic system 10 creates a current film-thickness profile of the other wafer from measurement values of the film thickness obtained from the film-thickness sensor 42 (see FIG. 1) during polishing of the other wafer, and determines pressures in the pressure chambers C1 to C4 for minimizing a difference between the current film-thickness profile and a target film-thickness profile based on the polishing-rate responsiveness profile. In another embodiment, the arithmetic system 10 creates a film-thickness profile before polishing of the wafer W and a film-thickness profile after polishing of the wafer W which has been used to create the polishing-rate profile, and determines pressures in the pressure chambers C1 to C4 based on the film-thickness profile before the polishing, the film-thickness profile after the polishing, a target film-thickness profile, and the polishing-rate responsiveness profile.

As described above, the polishing-rate responsiveness profile determined by the calculation is close to the actual polishing-rate responsiveness profile, but the polishing rate may slightly change depending on the polishing liquid (e.g., slurry) present on the polishing pad 2 and a temperature of the polishing surface 2a of the polishing pad 2. Thus, in one embodiment, a correction factor, which will be described below, is further used to improve an accuracy of the polishing-rate responsiveness profile.

The correction factor is a factor to eliminate a difference between the actual polishing-rate profile and the virtual polishing-rate profile. The arithmetic system 10 calculates a correction factor G(r) that satisfies the following formula after calculating the polishing-rate coefficient F(n) that minimizes the above formula (1).

$$Rate ( r ) - G ( r ) * {\sum }_{n = 1}^{n t} [ AP ( n ) * F ( n ) * P ( n , r ) ] = 0 \qquad ( 3 )$$

The correction factor G(r) is calculated for each radial position on the wafer W.

The arithmetic system 10 creates a polishing-rate responsiveness profile using the following formula (4) instead of the above formula (2).

$$Resp ( n , r ) = G ( r ) * F ( n ) * P ( n , r ) \qquad ( 4 )$$

The arithmetic system 10 multiplies the pressing-pressure responsiveness profile by the determined polishing-rate coefficient F(n) and the determined correction factor G(r) to calculate the polishing-rate responsiveness profile represented by the above formula (4).

In one embodiment, the arithmetic system 10 may calculate the polishing-rate coefficient F(n) and the polishing-rate offset Offset(r) that minimize the above formula (1′) or (1″), and then calculate the correction factor G(r) that eliminates the difference between the actual polishing-rate profile and the virtual polishing-rate profile. The arithmetic system 10 may calculate (create) the polishing-rate responsiveness profile by adding the determined polishing-rate offset Offset(r) to a value which is determined by multiplying the pressing-pressure responsiveness profile by the determined polishing-rate coefficient F(n) and the determined correction factor G(r).

The polishing rate may also change depending on changes over time in consumables, such as the polishing pad 2, or the retainer ring 32 of the polishing head 7. For example, generally, the polishing surface 2a of the polishing pad 2a is slightly scraped off by a dresser each time polishing of a wafer is finished so that the polishing surface 2a is regenerated. Such an operation is referred to as dressing of the polishing pad 2. As the dressing of the polishing pad 2 is repeated, a thickness of the polishing pad 2 is gradually reduced, and as a result, a polishing rate of a wafer may be affected.

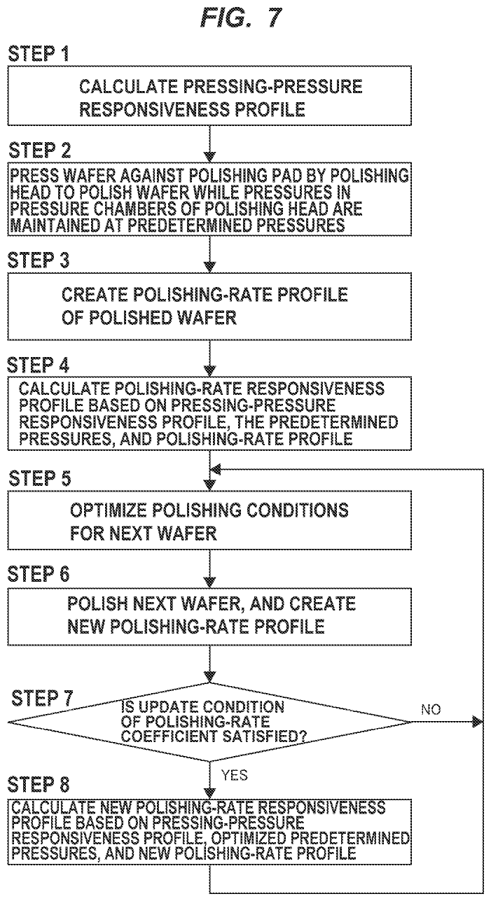

Thus, the above-described correction factor G(r) may be updated when a predetermined update condition is satisfied. An embodiment of updating the correction factor G(r) will be described below with reference to a flowchart shown in FIG. 7. Steps 1 to 4 shown in FIG. 7 are the same as the steps 1 to 4 shown in FIG. 3, and duplicated descriptions will be omitted.

In step 5, polishing conditions for a next wafer are optimized. For example, the arithmetic system 10 creates a film-thickness profile before the polishing of the wafer W in the step 2 and a film-thickness profile after the polishing of the wafer W in the step 2, and determines pressures in the pressure chambers C1 to C4 based on the film-thickness profile before the polishing, the film-thickness profile after the polishing, a target film-thickness profile, and the polishing-rate responsiveness profile.

In step 6, the polishing apparatus shown in FIG. 1 polishes the next wafer under the optimized polishing conditions, and the arithmetic system 10 creates a new polishing-rate profile. The optimization of the polishing conditions in the step 5 may be performed during polishing of the next wafer in the step 6. For example, the arithmetic system 10 creates a current film-thickness profile of the next wafer from measurement values of the film thickness obtained from the film-thickness sensor 42 (see FIG. 1) during polishing of the next wafer, and determines pressures in the pressure chambers C1 to C4 for minimizing the difference between the current film-thickness profile and the target film-thickness profile based on the polishing-rate responsiveness profile.

In step 7, the arithmetic system 10 determines whether the update condition for the polishing-rate coefficient has been satisfied. Examples of the update condition of the polishing-rate coefficient includes the followings:
the number of polished wafers has reached a predetermined number (the predetermined number may be one);
the consumable member, such as the polishing pad 2 or the retainer ring 32, has reached a predetermined usage time; and
a difference between a predicted film-thickness profile and an actual film-thickness profile exceeds an allowable value (the predicted film-thickness profile can be created from an initial film-thickness profile, the polishing-rate responsiveness profile, the pressures in the pressure chambers C1 to C4, and the polishing time).

When the update condition for the polishing-rate coefficient is satisfied, in step 8, the arithmetic system 10 updates the polishing-rate responsiveness profile by creating a new polishing-rate responsiveness profile based on the pressing-pressure responsiveness profile calculated in the step 1, the pressures in the pressure chambers C1 to C4 optimized in the step 5, and the new polishing-rate profile calculated in the step 6, and replacing the existing polishing-rate responsiveness profile with the new polishing-rate responsiveness profile.

In the step 8, when the update condition of the polishing-rate coefficient is not satisfied, the operation flow is returned to the step 5. The polishing conditions for a next wafer are optimized, and then the next wafer is polished.

According to this embodiment, the arithmetic system 10 can create the polishing-rate responsiveness profile that reflects a change over time in the consumable, such as the polishing pad 2 or the retainer ring 32.

The arithmetic system 10 operates according to the instructions contained in the programs electrically stored in the memory 10a to perform the operations of the above-described embodiments. For example, the arithmetic system 10 performs the simulation to calculate the pressing-pressure responsiveness profile indicating the distribution of the pressing pressure, which is to be applied from the workpiece to the polishing pad 2, changed in response to the changes in the unit pressure in the pressure chambers, creates the polishing-rate profile indicating the distribution of the polishing rate of the workpiece polished by pressing the workpiece against the polishing pad 2 while the pressures in the pressure chambers are maintained at predetermined pressures, and creates the polishing-rate responsiveness profile based on the pressing-pressure responsiveness profile, the predetermined pressures, and the polishing-rate profile.

The programs to cause the arithmetic system 10 to perform the operations of each embodiment described above are stored in a non-transitory tangible computer-readable storage medium, and provided to the arithmetic system 10 via the storage medium. Alternatively, the programs may be input to the arithmetic system 10 via communication network, such as the Internet or a local area network.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a technique of calculating a responsiveness of a polishing rate to change in a pressure to press a workpiece, such as a wafer, a substrate, or a panel, for use in manufacturing of semiconductor devices, against a polishing pad.

### REFERENCE SIGNS LIST

2 polishing pad
2a polishing surface
5 polishing table
5a table shaft
7 polishing head
8 polishing-liquid supply nozzle
10 arithmetic system
10a memory
10b arithmetic device
14 support shaft
16 polishing-head oscillation arm
18 polishing-head shaft
21 table rotating motor
31 head body
32 retainer ring
34, 36 elastic membrane
40 rotary joint
42 film-thickness sensor
C1, C2, C3, C4, C5 pressure chamber
F1, F2, F3, F4, F5 gas delivery line
R1, R2, R3, R4, R5 pressure regulator

1. A method of creating a polishing-rate responsiveness profile indicating a distribution of responsiveness of a polishing rate to a pressure change in a pressure chamber when a workpiece for use in manufacturing of semiconductor devices is pressed against a polishing pad with an elastic membrane forming the pressure chamber therein, the method comprising:
performing simulation to calculate a pressing-pressure responsiveness profile indicating a distribution of pressing pressure, which is to be applied from the workpiece to the polishing pad, changed in response to a change in unit pressure in the pressure chamber;
pressing the workpiece against the polishing pad to polish the workpiece, while a predetermined pressure is maintained in the pressure chamber;
creating a polishing-rate profile indicating a distribution of polishing rate of the polished workpiece; and
creating the polishing-rate responsiveness profile based on the pressing-pressure responsiveness profile, the predetermined pressure, and the polishing-rate profile.

2. The method according to claim 1, wherein creating the polishing-rate responsiveness profile comprises:
multiplying the pressing-pressure responsiveness profile by the predetermined pressure and a polishing-rate coefficient to create a virtual polishing-rate profile;
determining the polishing-rate coefficient that minimizes a difference between the polishing-rate profile and the virtual polishing-rate profile; and
multiplying the pressing-pressure responsiveness profile by the determined polishing-rate coefficient to create the polishing-rate responsiveness profile.

3. The method according to claim 2, wherein the pressure chamber comprises a plurality of pressure chambers, and the polishing-rate coefficient comprises a plurality of polishing-rate coefficients corresponding to the plurality of pressure chambers, respectively.

4. The method according to claim 2, further comprising determining a correction factor that eliminates the difference between the polishing-rate profile and the virtual polishing-rate profile,
wherein multiplying the pressing-pressure responsiveness profile by the determined polishing-rate coefficient to create the polishing-rate responsiveness profile comprises multiplying the pressing-pressure responsiveness profile by the determined polishing-rate coefficient and the determined correction factor to create the polishing-rate responsiveness profile.

5. The method according to claim 1, wherein creating the polishing-rate responsiveness profile comprises:
adding a polishing-rate offset to a value determined by multiplying the pressing-pressure responsiveness profile by the predetermined pressure and a polishing-rate coefficient to create a virtual polishing-rate profile;
determining the polishing-rate coefficient and the polishing-rate offset that minimize a difference between the polishing-rate profile and the virtual polishing-rate profile; and
adding the determined polishing-rate offset to a value determined by multiplying the pressing-pressure responsiveness profile by the determined polishing-rate coefficient to create the polishing-rate responsiveness profile.

6. The method according to claim 5, wherein the pressure chamber comprises a plurality of pressure chambers, and the polishing-rate coefficient comprises a plurality of polishing-rate coefficients corresponding to the plurality of pressure chambers, respectively.

7. The method according to claim 5, further comprising determining a correction factor that eliminates the difference between the polishing-rate profile and the virtual polishing-rate profile,
wherein multiplying the pressing-pressure responsiveness profile by the determined polishing-rate coefficient to create the polishing-rate responsiveness profile comprises adding the determined polishing-rate offset to a value determined by multiplying the pressing-pressure responsiveness profile by the determined polishing-rate coefficient and the determined correction factor to create the polishing-rate responsiveness profile.

8. The method according to claim 1, wherein creating the pressing-pressure responsiveness profile comprises:
performing simulation to create a first pressing-pressure responsiveness profile indicating a distribution of the pressing pressure changed in response to a change from a first pressure to a second pressure in the pressure chamber;
performing simulation to create a second pressing-pressure responsiveness profile indicating a distribution of the pressing pressure changed in response to a change from a third pressure to a fourth pressure in the pressure chamber; and
creating the pressing-pressure responsiveness profile based on the first pressing-pressure responsiveness profile and the second pressing-pressure responsiveness profile.

9. The method according to claim 8, wherein creating the pressing-pressure responsiveness profile based on the first pressing-pressure responsiveness profile and the second pressing-pressure responsiveness profile comprises creating the pressing-pressure responsiveness profile by interpolation or extrapolation using the first pressing-pressure responsiveness profile and the second pressing-pressure responsiveness profile.

10. The method according to claim 8, wherein creating the pressing-pressure responsiveness profile based on the first pressing-pressure responsiveness profile and the second pressing-pressure responsiveness profile comprises inputting the first pressing-pressure responsiveness profile and the second pressing-pressure responsiveness profile into a model constructed by machine learning, and outputting the pressing-pressure responsiveness profile from the model.

11. The method according to claim 1, wherein the polishing-rate profile comprises one selected from a plurality of polishing-rate profiles created by polishing a plurality of workpieces, and
the plurality of polishing-rate profiles are obtained by:
pressing the plurality of workpieces one by one against the polishing pad to polish the plurality of workpieces with different pressures set in the pressure chamber for each of the plurality of workpieces; and
creating the plurality of polishing-rate profiles indicating distributions of polishing rate of the plurality of polished workpieces.

12. The method according to claim 1, further comprising optimizing a polishing condition for other workpiece using the polishing-rate responsiveness profile.

13. The method according to claim 12, wherein optimizing the polishing condition for the other workpiece comprises:
creating a current film-thickness profile of the other workpiece, while the other workpiece is polished; and
determining the pressure in the pressure chamber for minimizing a difference between the current film-thickness profile and a target film-thickness profile based on the polishing-rate responsiveness profile.

14. The method according to claim 12, wherein optimizing the polishing condition for the other workpiece comprises:
creating a film-thickness profile before the polishing of the workpiece and a film-thickness profile after the polishing of the workpiece which has been used to create the polishing-rate profile; and
determining the pressure in the pressure chamber based on the film-thickness profile before the polishing, the film-thickness profile after the polishing, a target film-thickness profile, and the polishing-rate responsiveness profile.

15. A polishing method comprising:
optimizing a polishing condition for a workpiece using the polishing-rate responsiveness profile created by the method according to claim 1; and
pressing the workpiece against the polishing pad with the elastic membrane to polish the workpiece under the optimized polishing condition.

16. A computer-readable storage medium storing a program to cause a computer to create a polishing-rate responsiveness profile indicating a distribution of responsiveness of a polishing rate to a pressure change in a pressure chamber when a workpiece for use in manufacturing of semiconductor devices is pressed against a polishing pad with an elastic membrane forming the pressure chamber therein, the program being configured to cause the computer to perform the steps of:
performing simulation to calculate a pressing-pressure responsiveness profile indicating a distribution of pressing pressure, which is to be applied from the workpiece to the polishing pad, changed in response to a change in unit pressure in the pressure chamber;
creating a polishing-rate profile indicating a distribution of polishing rate of the workpiece polished by pressing the workpiece against the polishing pad while a predetermined pressure is maintained in the pressure chamber; and
creating the polishing-rate responsiveness profile based on the pressing-pressure responsiveness profile, the predetermined pressure, and the polishing-rate profile.
